(19) United States
(12) Patent Application Publication
(10) Pub. No.: US 2024/0079524 A1
(43) Pub. Date: Mar. 7, 2024

(54) SEMICONDUCTOR DEVICE

(71) Applicant: EPISTAR CORPORATION, Hsinchu (TW)

(72) Inventors: Wei-Jen HSUEH, Hsinchu (TW); Shih-Chang LEE, Hsinchu (TW); Kuo-Feng HUANG, Hsinchu (TW); Wen-Luh LIAO, Hsinchu (TW); Jiong-Chaso SU, Hsinchu (TW); Yi-Chieh LIN, Hsinchu (TW); Hsuan-Le LIN, Hsinchu (TW)

(21) Appl. No.: 18/242,758

(22) Filed: Sep. 6, 2023

(30) Foreign Application Priority Data
Sep. 7, 2022 (TW) 111133942

(51) Int. Cl. H01L 33/30; H01L 33/04

(52) U.S. Cl. CPC H01L 33/30; H01L 33/04

(57) ABSTRACT

A semiconductor device comprises a first semiconductor structure, a second semiconductor structure located on the first semiconductor structure, and an active layer located between the first semiconductor structure and the second semiconductor structure. The first semiconductor structure has a first conductivity type, and includes a plurality of first layers and a plurality of second layers alternately stacked. The second semiconductor structure has a second conductivity type opposite to the first conductivity type. The plurality of first layers and the plurality of second layers include indium and phosphorus, and the plurality of first layers and the plurality of second layers respectively have a first indium atomic percentage and a second indium atomic percentage. The second indium atomic percentage is different from the first indium atomic percentage.

### CROSS REFERENCE TO RELATED APPLICATION

This application claims the right of priority based on TW Application Serial No. 111133942, filed on Sep. 7, 2022, and the content of which is hereby incorporated by reference in its entirety.

### TECHNICAL FIELD

The disclosure relates to a semiconductor device, and particularly to a semiconductor light-emitting device.

### Description of Background Art

Semiconductor devices can be applied to a wide range of applications. Research and development of related materials have been continuously carried out. For example, a group III-V semiconductor material containing a group III element and a group V element may be applied to various optoelectronic semiconductor devices, such as light-emitting diodes (LEDs), laser diodes (LDs), photoelectric detectors, solar cells or power devices (such as switches or rectifiers). These optoelectronic semiconductor devices can be applied in various fields, such as illumination, medical care, display, communication, sensing, or power supply system. For example, in semiconductor light-emitting devices, LEDs have low energy consumption, rapid response, small volume and long operating lifetime, thus are widely used.

### SUMMARY OF THE DISCLOSURE

The present disclosure provides a semiconductor device. The semiconductor device comprises a first semiconductor structure, a second semiconductor structure located on the first semiconductor structure, and an active layer located between the first semiconductor structure and the second semiconductor structure. The first semiconductor structure has a first conductivity type, and includes a plurality of first layers and a plurality of second layers alternately stacked. The second semiconductor structure has a second conductivity type opposite to the first conductivity type. The plurality of first layers and the plurality of second layers include indium and phosphorus, and the plurality of first layers and the plurality of second layers respectively have a first indium atomic percentage and a second indium atomic percentage. The second indium atomic percentage is different from the first indium atomic percentage.

### BRIEF DESCRIPTION OF THE DRAWINGS

The foregoing aspects and many of the attendant advantages of the present disclosure will become more readily appreciated as the same becomes better understood by reference to the following detailed description, when taken in conjunction with the accompanying drawings, wherein:

FIG. 1 shows a schematic cross-sectional view of a semiconductor device according to one embodiment of the present disclosure;

FIG. 2 shows a schematic cross-sectional view of a semiconductor device according to one embodiment of the present disclosure;

FIG. 3A shows a schematic figure of band structure according to a superlattice structure in one embodiment of the present disclosure;

FIG. 3B shows a schematic figure of band structure according to a superlattice structure in one embodiment of the present disclosure;

FIG. 3C shows a schematic figure of band structure according to a superlattice structure in one embodiment of the present disclosure;

FIG. 3D shows a schematic figure of band structure according to a superlattice structure in one embodiment of the present disclosure;

FIG. 4A shows a top schematic view of a semiconductor device according to one embodiment of the present disclosure;

FIG. 4B shows a schematic cross-sectional view of the semiconductor device in FIG. 4A along section line A-A′;

FIG. 5 shows a schematic cross-sectional view of a semiconductor device according to one embodiment of the present disclosure;

FIG. 6 shows a schematic cross-sectional view of a package structure of a semiconductor device according to an embodiment of the present disclosure.

### DETAILED DESCRIPTION OF PREFERRED EMBODIMENTS

Exemplary embodiments of the present disclosure will be described in detail with reference to the accompanying drawings hereafter. The following embodiments are given by way of illustration with Cartesian Coordinates (X, Y, Z axes) to help those skilled in the art fully understand the spirit of the present disclosure. Hence, it should be noted that the present disclosure is not limited to the embodiments herein and can be realized in various forms. Further, the drawings are not precise scale and components may be exaggerated in view of width, height, length, etc. Herein, the similar or identical reference numerals will denote the similar or identical components throughout the drawings. In the embodiments of the present disclosure, if not described otherwise, the term “horizontal” means any value or vector along X-axis, Y-axis or on X-Y plane. The term “vertical” means any value or vector along Z-axis, and terms such as “below”, “above”, “under”, “on”, “top” and “bottom” may be used to describe special relationships along Z-axis between different devices or elements. The term “corresponding” may be used to describe different elements are overlapped horizontally (on X-Y plane). The term “coplanar” may be used to describe surfaces of different elements are vertically on the same level.

The semiconductor device of the present disclosure can be light-emitting device (such as light-emitting diode or laser diode) or light absorption device (such as photo-detector). Qualitative or quantitative analysis of the composition and/or dopant contained in each layer of the semiconductor device of the present disclosure may be conducted by any suitable method, for example, a secondary ion mass spectrometer (SIMS). A thickness of each layer may be obtained by any suitable method, such as a transmission electron microscopy (TEM) or a scanning electron microscope (SEM).

In addition, if not otherwise specified, a description similar to “a first layer/structure is on or under a second layer/structure” may include an embodiment in which the first layer/structure directly (or physically) contacts the second layer/structure, and may also include an embodiment in which another structure is provided between the first layer/structure and the second layer/structure, such that the first layer/structure and the second layer/structure do not directly contact each other. Furthermore, it should be realized that a positional relationship of a layer/structure may be altered when being observed in different orientations.

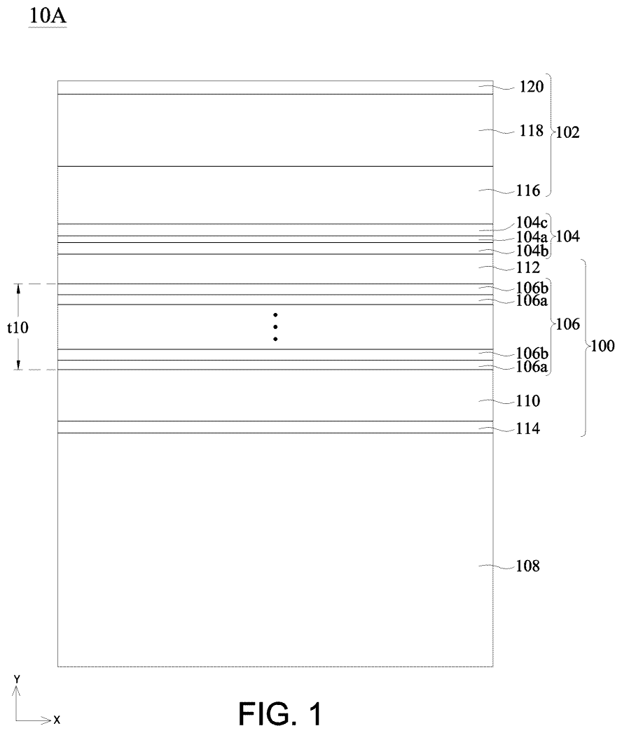

FIG. 1 shows a schematic cross-sectional view of a semiconductor device 10A according to one embodiment of the present disclosure. The semiconductor device 10A includes a first semiconductor structure 100, a second semiconductor structure 102 located on the first semiconductor structure 100, and an active structure 104 located between the first semiconductor structure 100 and the second semiconductor structure 102. The active structure 104 includes an active layer 104a. In one embodiment, the active structure 104 can further include a first confinement layer 104b and a second confinement layer 104c respectively located at two sides of the active layer 104a. The first semiconductor structure 100 has a first conductivity type, and the second semiconductor structure 102 has a second conductivity type opposite to the first conductivity type. For example, the first semiconductor structure 100 and the second semiconductor structure 102 can respectively be n-type semiconductor and p-type semiconductor, or p-type semiconductor and n-type semiconductor. The n-type semiconductor and the p-type semiconductor can be formed by doping dopants into an intrinsic semiconductor. In one embodiment, the n-type semiconductor may be, for example, a semiconductor doped with tellurium (Te) or silicon (Si), and the p-type semiconductor may be, for example, a semiconductor doped with carbon (C), zinc (Zn) or magnesium (Mg). As shown in FIG. 1, the semiconductor device 10A can optionally include a base 108 under the first semiconductor structure 100, the second semiconductor structure 102 and the active structure 104. In one embodiment, the base 108 connects the first semiconductor structure 100.

The base 108 can include conductive material or insulating material. The conductive material can include gallium arsenide (GaAs), indium phosphide (InP), silicon carbide (SiC), gallium phosphide (GaP), zinc oxide (ZnO), gallium nitride (GaN), aluminum nitride (AlN), germanium (Ge) or silicon (Si). The insulating materials can include sapphire. In the embodiment shown in FIG. 1, the base 108 is a growth substrate. In other embodiments, the base 108 can be a bonding substrate instead of the growth substrate, which is bonded to the first semiconductor structure 100 through a bonding structure (not shown).

The first semiconductor structure 100, the second semiconductor structure 102 and the active structure 104 can include same group of III-V compound semiconductor material. The III-V compound semiconductor material can include binary, ternary or quaternary III-V compound semiconductors, such as AlInGaAs series, AlInGaP series, AlInGaN series or InGaAsP series. The AlInGaAs series can be represented by (Alₓ₁In₍₁₋ₓ₁₎)₁₋ₓ₂Gaₓ₂As, wherein 0≤x1, x2≤1. The AlInGaP series can be represented by (Al_{y1}In_{(1-y1)})_{1-y2}Ga_{y2}P, wherein 0≤y1, y2≤1. The AlInGaN series can be represented by (Al_{z1}In_{(1-z1)})_{1-z2}Ga_{z2}N, wherein 0≤z1, z2≤1. The InGaAsP series can be represented by In_{z3}Ga_{1-z3}As_{z4}P_{1-z4}, wherein 0≤z3, z4≤1.

The semiconductor device 10A can include double heterostructure (DH), double-side double heterostructure (DDH) or multiple quantum wells structure (MQW). For example, the active layer 104a can include a plurality of barrier layers (not shown) and a plurality of well layers (not shown) that are alternately stacked with each other to form aforementioned multiple quantum wells structure. When the semiconductor device 10A is in operation, the active structure 104 emits a light with a peak wavelength, and the light can include visible light and/or invisible light. The active layer 104a has a bandgap determined by the material composition of the active structure 104, and the peak wavelength is corresponding to the bandgap. For example, when the material of the active structure 104 includes InGaN series, it can emit blue light or deep blue light with a peak wavelength of 400 nm to 490 nm, or green light with a peak wavelength of 490 nm to 550 nm; when the material of the active structure 104 includes AlGaN series, it can emit ultraviolet light with a peak wavelength of 250 nm to 400 nm; when the material of the active structure 104 includes InGaAs series, InGaAsP series, AlGaAs series or AlGaInAs series, it can emit infrared light with a peak wavelength of 700 to 1700 nm; when the material of the active structure 104 includes InGaP series or AlGaInP series, it can emit red light with a peak wavelength of 610 nm to 700 nm, or yellow light with a peak wavelength of 530 nm to 600 nm.

As shown in FIG. 1, the first semiconductor structure 100 can include a plurality of first layers 106a and a plurality of second layers 106b that are alternately stacked with each other, so as to form a first superlattice structure 106. According to one embodiment, the first semiconductor structure 100 may have 20 to 70 pairs of the first layer 106a and the second layer 106b. The first layer 106a of each pair can have same or different thicknesses, and the second layers 106b of each pair can have same or different thicknesses. In one embodiment, the first layer 106a and the second layer 106b respectively have a first thickness t1 and a second thickness t2. The first thickness t1 and the second thickness t2 can be in a range of 30 Å to 300 Å. For each or one pair of the first layer 106a and the second layer 106b, the first thickness t1 and the second thickness t2 can be the same or different. In one embodiment, for each or one pair of the first layer 106a and the second layer 106b, the second thickness t2 can be equal to or smaller than the first thickness t1. The first superlattice structure 106 has a first total thickness t10. In one embodiment, the first total thickness t10 can be between 0.1 μm to 4.5 μm, for example, between 0.5 μm to 3 μm or between 1 μm to 2.5 μm. In each pair, the first layer 106a and the second layer 106b can include ternary or quaternary III-V compound semiconductor, which is compound of at least three elements selected from aluminum (Al), gallium (Ga), indium (In), phosphorus (P), arsenic (As) or nitrogen (N). In one embodiment, the first layer 106a and the second layer 106b of each pair do not include nitrogen (N). In one embodiment, the first layer 106a and/or the second layer 106b of each or one pair includes (Aₓ₃B₁₋ₓ₃)_{1-y3}In_{y3}P, and elements A and B are selected from group III elements other than indium (In). According to one embodiment, elements A and B can be Al and Ga respectively, and 0≤x3≤1, 0<y3≤1. In one embodiment, the first layer 106a includes (Alₓ₁₁Ga₁₋ₓ₁₁)_{1-y11}In_{y11}P and the second layer 106b includes (Alₓ₁₂Ga₁₋ₓ₁₂)_{1-y12}In_{y12}P, and 0<x11, x12, y11, y12<1 and y11<y12.

According to some embodiments of the present disclosure, the first layer 106a and the second layer 106b of each pair can include the same material but with different composition ratios. In one embodiment, the first layer 106a and the second layer 106b in each pair include indium and phosphorus. The first layer 106a has a first indium atomic percentage and the second layer 106b has a second indium atomic percentage different from the first indium atomic percentage. According to one embodiment, when the first semiconductor structure 100 is the n-type semiconductor, concentration of two-dimensional electron gas (2DEG) within the first semiconductor structure 100 can be increased by differentiating the first indium atomic percentage of the first layer 106a from the second indium atomic percentage of the second layer 106b, so as to increase speed of carrier recombination in the semiconductor device 10A. Specifically, the first indium atomic percentage and the second indium atomic percentage are respectively corresponding to an indium atomic ratio of the first layer 106a and an indium atomic ratio of the second layer 106b, which can be obtained through suitable component analysis methods, such as Energy Dispersive Spectrometer (EDX) or SIMS. For example, when the first layer 106a includes (Alₓ₄Ga₁₋ₓ₄)_{1y4}In_{y4}P and the second layer 106b includes (Alₓ₅Ga₁₋ₓ₅)_{1-y5}In_{y5}P (0<x4, x5, y4, y5<1), through EDX analysis the indium atomic ratio of the first layer 106a is obtained as y4 and the indium atomic ratio of the second layer 106b is obtained as y5. Accordingly, the first indium atomic percentage can be defined as y4*100%, and the second indium atomic percentage can be defined as y5*100%. For example, when y4=0.5 and y5=0.6, the first indium atomic percentage is 50% and the second indium atomic percentage is 60%. Indium atomic percentage represents a percentage of the total number of indium elements to the total number of all group III elements. In some embodiments, the first indium atomic percentage and the second indium atomic percentage can respectively be in a range of 30% to 70%, for example, between 40% to 60%.

In each or one pair of the first layer 106a and the second layer 106b, a lattice constant of the first layer 106a and a lattice constant of the second layer 106b can be the same or different. The “lattice constant” herein means a lattice constant a0 of a layer/structure without any substantial strain. In one embodiment, the first layer 106a and the second layer 106b respectively have a first lattice constant a₁ and a second lattice constant a₂. In one embodiment, the first lattice constant a₁ and/or the second lattice constant a₂ can be in a range of 5.5 Å to 5.8 Å. In some embodiments, when the base 108 is a GaAs growth substrate and the first indium atomic percentage of the first layer 106a (or the second indium atomic percentage of the second layer 106b) is 50%, the base 108 and the first layer 106a (or the second layer 106b) are latticed-matched. When the first indium atomic percentage (or the second indium atomic percentage) is smaller than 50%, the lattice constant of the first layer 106a (or of the second layer 106b) is smaller than the lattice constant of the base 108, so as to introduce tensile strain into the first layer 106a (or the second layer 106b). When the first indium atomic percentage (or the second indium atomic percentage) is larger than 50%, the lattice constant of the first layer 106a (or of the second layer 106b) is larger than the lattice constant of the base 108, so as to introduce compressive strain into the first layer 106a (or the second layer 106b). In some embodiments, the second lattice constant a₂ of the second layer 106b can be larger than or smaller than the first lattice constant a₁ of the first layer 106a. In other words, the second indium atomic percentage of the second layer 106b can be larger than or smaller than the first indium atomic percentage of the first layer 106a.

In each or one pair, the first layer 106a and the second layer 106b can include different materials. In some embodiments, the first layer 106a or the second layer 106b can include compound semiconductor having antimony (Sb). In one embodiment, the first layer 106a or the second layer 106b includes In_{y0}C_{1-y0}Sbₓ₀D₁₋ₓ₀, and element C is selected from group III elements other than indium and element D is selected from group V elements other than antimony (Sb). In one embodiment, element C and element D can respectively be aluminum (Al) and phosphorus (P), and 0≤x0≤1, 0<y0≤1. In one embodiment, the first layer 106a includes Al₁₋₂₀In_{y20}P and the second layer 106b includes In_{y23}Al_{1-y23}Sbₓ₂₃P₁₋ₓ₂₃, and 0<x23, y20, y23<1. When the first semiconductor structure 100 is the p-type semiconductor, concentration of two-dimensional hole gas (2DHG) within the first semiconductor structure 100 can be increased by incorporating the compound semiconductor having Sb in the second layer 106b. Thus, in the first semiconductor structure 100, the serial resistance can be reduced and hole mobility can be increased, and carrier recombination speed of the semiconductor device 10A can be improved.

In some embodiments, with respect to the base 108 (such as the GaAs growth substrate), the first superlattice structure 106 can have compressive strain, tensile strain or no strain. Besides, in some embodiments, when the first semiconductor structure 100 is the n-type semiconductor, electron mobility of the first semiconductor structure 100 can be improved by introducing tensile strain into the first superlattice structure 106, for example, making the first layer 106a have tensile strain and the second layer 106b have no strain. Or, when the first semiconductor structure 100 is the p-type semiconductor, hole mobility of the first semiconductor structure 100 can be improved by introducing compressive strain into the first superlattice structure 106, for example, making the first layer 106a have compressive strain and the second layer 106b have no strain. Through improving the electron mobility or the hole mobility of the first semiconductor structure 100, carrier recombination speed of the semiconductor device 10A can be increased.

In one embodiment, in each pair, the first layer 106a has a first valence band (Ev1), a first conduction band (Ec1) and a first bandgap (ΔE1=Ec1−Ev1), and the second layer 106b has a second valence band (Ev2), a second conduction band (Ec2) and a second bandgap (ΔE2=Ec2−Ev2). In one embodiment, when the first semiconductor structure 100 is the n-type semiconductor, a gap of conduction band (ΔEc) between the first conduction band (Ec1) and the second conduction band (Ec2) can be in a range of 0.05 eV to 1 eV, so as to form carrier-confinement effect. For instance, the second conduction band (Ec2) can be lower than the first conduction band (Ec1) by 0.05 eV to 1 eV. In one embodiment, the first bandgap (ΔE1) of the first layer 106a and the second bandgap (ΔE2) of the second layer 106b can be larger than the bandgap of the active layer 104a, and a wavelength corresponding to the first bandgap (ΔE1) of the first layer 106a and a wavelength corresponding to the second bandgap (ΔE2) of the second layer 106b are smaller than the peak wavelength of the light emitted from the active structure 104. Thus, the first layer 106a and the second layer 106b do not absorb the light. In some embodiments, a difference between the peak wavelength of the light and the wavelength corresponding to the first bandgap (ΔE1) (or the wavelength corresponding to the second bandgap (ΔE2)) is equal to or larger than 30 nm. For example, when the active structure 104 emits a red light with the peak wavelength of 660 nm, the wavelength corresponding to the first bandgap (ΔE1) and/or the wavelength corresponding to the second bandgap (ΔE2) can be equal to or smaller than 630 nm.

In some embodiments, the first layer 106a and the second layer 106b can respectively have strains with respect to the base 108, and the strain of the first layer 106a is opposite to the strain of the second layer 106b. For instance, with respect to the base 108 (such as the GaAs growth substrate), the first layer 106a and the second layer 106b can respectively have the tensile strain and the compressive strain (or the compressive strain and the tensile strain), so that the strain of the first layer 106a can be compensated by the strain of the second layer 106b. In some embodiments, the base 108 has a third lattice constant a₃, and the third lattice constant a₃ can be between the first lattice constant a₁ of the first layer 106a and the second lattice constant a₂ of the second layer 106b. In some embodiments, each pair of the first layer 106a and the second layer 106b have an equivalent lattice constant a_{q1}, and the equivalent lattice constant a_{q1} can be substantially same as the third lattice constant a₃ so that the first superlattice structure 106 and the base 108 can keep latticed-matching. More specifically, as the first layer 106a has the first lattice constant a₁ and the first thickness t1 and the second layer 106b has the second lattice constant a₂ and the second thickness t2, the equivalent lattice constant a_{q1} can be expressed as a_{q1}=(a₁*t1+a₂*t2)/(t1+t2). There may be a lattice constant difference (Δa₁) between the equivalent lattice constant a_{q1} and the third lattice constant a₃ (Δa₁=a_{q1}−a₃). In some embodiments, a ratio of the lattice constant difference (Δa₁) to the third lattice constant a₃ can be equal to or smaller than ±2000 ppm, i.e., ±0.2%, so that the first superlattice structure 106 and the base 108 can keep latticed-matching and avoid delamination formed therebetween.

According to the embodiments in which the first layer 106a and the second layer 106b have opposite strains, the first layer 106a and the second layer 106b can include Al_{1-y6}In_{y6}P, Ga_{1-y7}In_{y7}P or (Alₓ₈Ga₍₁₋ₓ₈₎)_{1-y8}In_{y8}P, and 0<x8<1, 0<y6, y7, y8<1. In one embodiment, the first layer 106a and the second layer 106b can include same material but with different composition ratios. For example, the first layer 106a can include Al_{1-y31}In_{y31}P and the second layer 106b can include Al_{1-y32}In_{y32}P while y31<y32, thus the first layer 106a and the second layer 106b respectively have the tensile strain and the compressive strain with respect to the base 108. As the first layer 106a and the second layer 106b are AlInP, the electron mobilities thereof and the wavelengths corresponding to the first bandgap (ΔE1) and the second bandgap (ΔE2) increase with the indium atomic ratios (y31, y32). In one embodiment, when the base 108 is the GaAs substrate and the peak wavelength of the light emitted from the active structure 104 is between 580 nm to 620 nm, y31 can be between 0.3 to 0.4 and y32 can be between 0.59 to 0.69 so that the first bandgap (ΔE1) can have a corresponding wavelength between 515 nm to 525 nm and the second bandgap (ΔE2) can have a corresponding wavelength between 535 nm to 605 nm. As such, the second layer 106b with higher indium atomic ratio (y32) can have higher electron mobility to increase carrier recombination speed of the semiconductor device 10A. In one embodiment, the first layer 106a and the second layer 106b can include different materials. For example, the first layer 106a can include Ga_{1-y33}In_{y33}P and the second layer 106b can include Al_{1-y34}In_{y34}P while y33<y34, thus the first layer 106a and the second layer 106b respectively have the tensile strain and the compressive strain with respect to the base 108. When the first layer 106a is GaInP, the electron mobility thereof and the wavelength corresponding to the first bandgap (ΔE1) increase with the indium atomic ratio (y33). In one embodiment, the indium atomic ratio (y33) of the first layer 106a is equal to or larger than 0.3 to ensure the first layer 106a can have high electron mobility, such as equal to or larger than 150 cm²/V sec. In one embodiment, when the base 108 is the GaAs substrate and the peak wavelength of the light emitted from the active structure 104 is between 580 nm to 620 nm, y33 can be between 0.3 to 0.4 and y34 can be between 0.59 to 0.69, so that the first bandgap (ΔE1) can have a corresponding wavelength between 560 nm to 605 nm and the second bandgap (ΔE2) to can have a corresponding wavelength between 535 nm to 605 nm.

In above two embodiments, through adjusting indium atomic ratios of the first layer 106a and the second layer 106b, the first layer 106a and the second layer 106b respectively have the tensile strain and the compressive strain with respect to the base 108, and the wavelengths corresponding to the first bandgap (ΔE1) of the first layer 106a and the second bandgap (ΔE2) of the second layer 106b can be smaller than the peak wavelength of the light. When the first semiconductor structure 100 is the n-type semiconductor, the first layer 106a with the tensile strain can improve the electron mobility of the first semiconductor structure 100. When the first semiconductor structure 100 is the p-type semiconductor, the second layer 106b with the compressive strain can improve the hole mobility of the first semiconductor structure 100. In other words, the first layer 106a and the second layer 106b can respectively improve the electron mobility and the hole mobility of the first semiconductor structure 100 since they have opposite strains, so that the carrier recombination speed of the semiconductor device 10A can be increased.

Referring to FIG. 1. the first semiconductor structure 100 can optionally include a first semiconductor layer 110, a second semiconductor layer 112 and/or a first semiconductor contact layer 114. The first semiconductor layer 110 can be disposed between the base 108 and the first superlattice structure 106. The second semiconductor layer 112 can be disposed between the first superlattice structure 106 and the active structure 104. The first semiconductor contact layer 114 can be disposed between the first semiconductor layer 110 and the base 108. Besides, the second semiconductor structure 102 can optionally include a third semiconductor layer 116, a fourth semiconductor layer 118 and/or a second semiconductor contact layer 120. The third semiconductor layer 116 can be disposed on the active structure 104. The fourth semiconductor layer 118 can be disposed on the third semiconductor layer 116. The second semiconductor contact layer 120 can be disposed on the fourth semiconductor layer 118. As shown in FIG. 1, the second semiconductor layer 112 and the third semiconductor layer 116 are located at two sides of the active structure 104 respectively, and can be cladding layers to respectively provide electrons and holes (or holes and electrons) combined in the active structure 104. The first semiconductor layer 110 and the fourth semiconductor layer 118 can be window layers to improve current spreading within the semiconductor device 10A, or can be light extraction layers to enhance light extraction efficiency. In one embodiment, the first semiconductor structure 100 does not include the first semiconductor layer 110 and the second semiconductor structure 102 does not include the fourth semiconductor layer 118, so as to reduce an overall thickness of the semiconductor device 10A. The first semiconductor contact layer 114 and the second semiconductor contact layer 120 can have high doping concentration, for example, between 1×10¹⁸/cm³ and 1×10¹⁹/cm³, so as to form low resistance interface with adjacent layers or components.

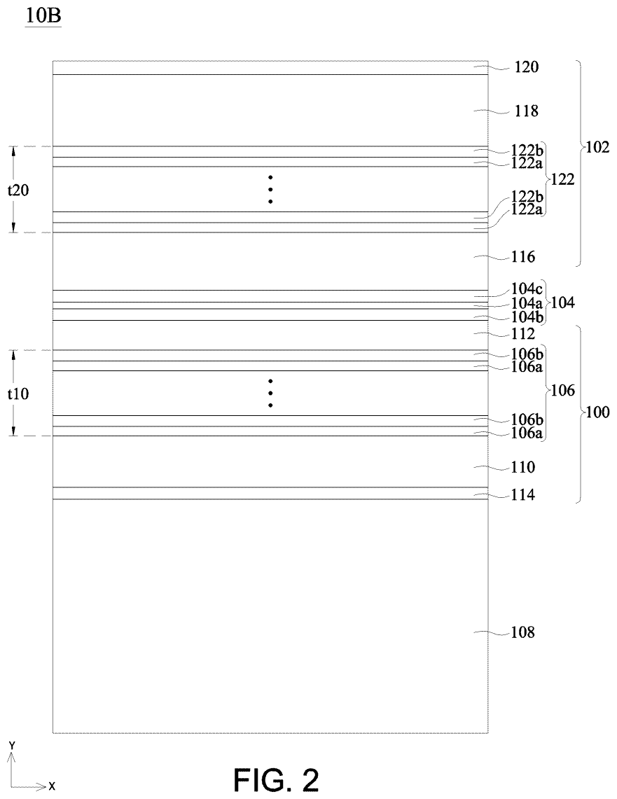

FIG. 2 shows a schematic cross-sectional view of a semiconductor device 10B according to one embodiment of the present disclosure. The semiconductor device 10B has similar structure as the semiconductor device 10A, but the second semiconductor structure 102 of the semiconductor device 10B further includes a plurality of third layers 122a and a plurality of fourth layers 122b that are alternately stacked with each other, so as to form a second superlattice structure 122. According to one embodiment, the second semiconductor structure 102 can have 20 to 50 pairs of the third layer 122a and the fourth layer 122b. Number of pair of the third layer 122a and the fourth layer 122b can be larger than, equal to or small than number of pair of the first layer 106a and the second layer 106b. The third layer 122a of each pair can have same or different thicknesses and the fourth layers 122b of each pair can have same or different thicknesses. In one embodiment, the third layer 122a and the fourth layer 122b respectively have a third thickness t3 and a fourth thickness t4. The third thickness t3 and the fourth thickness t4 can be in a range of 30 Å to 300 Å. For each or one pair of the third layer 122a and the fourth layer 122b, the third thickness t3 and the fourth thickness t4 can be the same or different. In one embodiment, for each or one pair of the third layer 122a and the fourth layer 122b, the fourth thickness t4 can be equal to or smaller than the third thickness t3. The second superlattice structure 122 has a second total thickness t20, which is equal to or smaller than the first total thickness t10 of the first superlattice structure 106. In one embodiment, the second total thickness t20 can be between 0.1 μm to 3 μm, for example, between 0.5 μm to 2 μm or between 1 μm to 1.5 μm.

In each pair, the third layer 122a and the fourth layer 122b can include ternary or quaternary III-V compound semiconductor, which is compound of at least three elements selected from aluminum (Al), gallium (Ga), indium (In), phosphorus (P), arsenic (As) or nitrogen (N). In one embodiment, the third layer 122a and the fourth layer 122b of each pair do not include nitrogen (N).

According to some embodiments of the present disclosure, the third layer 122a and the fourth layer 122b of each pair can include the same material but with different composition ratios. In one embodiment, the third layer 122a and the fourth layer 122b in each pair include indium and phosphorus. The third layer 122a has a third indium atomic percentage and the fourth layer 122b has a fourth indium atomic percentage different from the third indium atomic percentage. According to one embodiment, when the second semiconductor structure 102 is the p-type semiconductor, concentration of the two-dimensional hole gas (2DHG) within the second semiconductor structure 102 can be increased by differentiating the third indium atomic percentage of the third layer 122a from the fourth indium atomic percentage of the fourth layer 122b, so as to increase speed of carrier recombination in the semiconductor device 10B. Specifically, the third indium atomic percentage and the fourth indium atomic percentage are respectively corresponding to an indium atomic ratio of the third layer 122a and an indium atomic ratio of the fourth layer 122b, which can be obtained through EDX or SIMS. In some embodiments, the third indium atomic percentage and the fourth indium atomic percentage can respectively be in a range of 30% to 70%, for example, between 40% to 60%.

In each or one pair of the third layer 122a and the fourth layer 122b, a lattice constant of the third layer 122a and a lattice constant of the fourth layer 122b can be the same or different. In one embodiment, the third layer 122a and the fourth layer 122b respectively have a fourth lattice constant a₄ and a fifth lattice constant a₅. In one embodiment, the fourth lattice constant a₄ and/or the fifth lattice constant a₅ can be in a range of 5.5 Å to 5.8 Å. In some embodiments, when the base 108 is the GaAs growth substrate and the third indium atomic percentage of the third layer 122a (or the fourth indium atomic percentage of the fourth layer 122b) is 50%, the base 108 and the third layer 122a (or the fourth layer 122b) are latticed-matched. When the third indium atomic percentage (or the fourth indium atomic percentage) is smaller than 50%, the lattice constant of the third layer 122a (or of the fourth layer 122b) is smaller than the lattice constant of the base 108, so as to introduce tensile strain into the third layer 122a (or the fourth layer 122b). When the third indium atomic percentage (or the fourth indium atomic percentage) is larger than 50%, the lattice constant of the third layer 122a (or of the fourth layer 122b) is larger than the lattice constant of the base 108, so as to introduce compressive strain into the third layer 122a (or the fourth layer 122b). In some embodiments, the fifth lattice constant a₅ of the fourth layer 122b can be larger than or smaller than the fourth lattice constant a₄ of the third layer 122a. In other words, the fourth indium atomic percentage of the fourth layer 122b can be larger than or smaller than the third indium atomic percentage of the third layer 122a.

In each or one pair, the third layer 122a and the fourth layer 122b can include different materials. In some embodiments, the third layer 122a or the fourth layer 122b can include compound semiconductor having antimony. In one embodiment, the third layer 122a or the fourth layer 122b includes In_{y2}C_{1-y2}Sbₓ₂D₁₋ₓ₂, and element C is selected from group III elements other than indium (In) and element D is selected from group V elements other than antimony (Sb). In one embodiment, element C and element D can respectively be aluminum (Al) and phosphorus (P), and 0≤x2≤1, 0<y2≤1. In one embodiment, the third layer 122a includes Al_{1-y21}In_{y21}P and the fourth layer 122b includes In_{y2}Al_{1-y22}Sbₓ₂₂P₁₋ₓ₂₂, and 0<x22, y21, y22<1. When the second semiconductor structure 102 is the p-type semiconductor, the concentration of two-dimensional hole gas (2DHG) within the second semiconductor structure 102 can be increased by incorporating the compound semiconductor having Sb in the fourth layer 122b. Thus, in the second semiconductor structure 102, the serial resistance can be reduced and the hole mobility can be increased, and the carrier recombination speed of the semiconductor device 10B can be improved.

In some embodiments, with respect to the base 108 (such as the GaAs growth substrate), the second superlattice structure 122 can have compressive strain, tensile strain or no strain. Besides, in some embodiments, when the second semiconductor structure 102 is the n-type semiconductor, electron mobility of the second semiconductor structure 102 can be improved by introducing tensile strain into the second superlattice structure 122, for example, making the third layer 122a have tensile strain and the fourth layer 122b have no strain. Or, when the second semiconductor structure 102 is the p-type semiconductor, hole mobility of the second semiconductor structure 102 can be improved by introducing compressive strain into the second superlattice structure 122, for example, making the third layer 122a have compressive strain and the fourth layer 122b have no strain. Through improving the electron mobility or the hole mobility of the second semiconductor structure 102, carrier recombination speed of the semiconductor device 10B can be increased. In one embodiment, in each or one pair of the third layer 122a and the fourth layer 122b, the third layer 122a can include Al_{1-y13}In_{y13}P and the fourth layer 122b can include Al_{1-y14}In_{y14}P, and 0<y13, y14<1 and y13<y14.

In one embodiment, in each pair, the third layer 122a has a third valence band (Ev3), a third conduction band (Ec3) and a third bandgap (ΔE3=Ec3−Ev3), and the fourth layer 122b has a fourth valence band (Ev4), a fourth conduction band (Ec4) and a fourth bandgap (ΔE4=Ec4-Ev4). In one embodiment, when the second semiconductor structure 102 is the p-type semiconductor, a gap of valence band (ΔEv) between the third valence band (Ev3) and fourth valence band (Ev4) can be in a range of 0.05 eV to 1 eV, so as to form carrier-confinement effect. For instance, the fourth valence band (Ev4) can be higher than the third valence band (Ev3) by 0.05 eV to 1 eV. In one embodiment, the third bandgap (ΔE3) of the third layer 122a and the fourth bandgap (ΔE4) of the fourth layer 122b can be larger than the bandgap of the active layer 104a, and a wavelength corresponding to the third bandgap (ΔE3) of the third layer 122a and a wavelength corresponding to the fourth bandgap (ΔE4) of the fourth layer 122b can be smaller than the peak wavelength of the light emitted from the active structure 104. Thus, the third layer 122a and the fourth layer 122b do not absorb the light. In some embodiments, a difference between the peak wavelength of the light and the wavelength corresponding to the third bandgap (ΔE3) (or the wavelength corresponding to the fourth bandgap (ΔE4)) is equal to or larger than 30 nm. For example, when the active structure 104 emits a red light with the peak wavelength of 660 nm, the wavelength corresponding to the third bandgap (ΔE3) and the wavelength corresponding to the fourth bandgap (ΔE4) can be equal to or smaller than 630 nm.

In some embodiments, the third layer 122a and the fourth layer 122b can respectively have strain with respect to the base 108, and the strain of the third layer 122a is opposite to the strain of the fourth layer 122b. For instance, with respect to the base 108 (such as the GaAs growth substrate), the third layer 122a and the fourth layer 122b can respectively have the tensile strain and the compressive strain (or the compressive strain and the tensile strain), so that the strain of the third layer 122a can be compensated by the strain of the fourth layer 122b. In some embodiments, the third lattice constant a₃ of the base 108 can be between the fourth lattice constant a₄ of the third layer 122a and the fifth lattice constant a₅ of the fourth layer 122b. In some embodiments, each pair of the third layer 122a and the fourth layer 122b have an equivalent lattice constant a_{q2}, and the equivalent lattice constant a_{q2} can be substantially same as the third lattice constant a₃ so that the second superlattice structure 122 and the base 108 can keep latticed-matching. More specifically, as the third layer 122a has the fourth lattice constant a₄ and the third thickness t3 and the fourth layer 122b has the fifth lattice constant a₅ and the fourth thickness t4, the equivalent lattice constant a_{q2} can be expressed as a_{q2}=(a₄*t3+a₅*t4)/(t3+t3). There may be a lattice constant difference (Δa₂) between the equivalent lattice constant a_{q2} and the third lattice constant a₃ (Δa₂=a_{q2}−a₃). In some embodiments, a ratio of the lattice constant difference (Δa₂) to the third lattice constant a₃ can be equal to or smaller than ±2000 ppm, i.e., ±0.2%, so that the second superlattice structure 122 and the base 108 can keep latticed-matching and avoid delamination formed therebetween.

According to the embodiments in which the third layer 122a and the fourth layer 122b have opposite strains, the third layer 122a and the fourth layer 122b can include Al_{1-y6}In_{y6}P, Ga_{1-y7}In_{y7}P or (Alₓ₈Ga₍₁₋ₓ₈₎)_{1-y8}In_{y8}P, and 0<x8<1, 0<y6, y7, y8<1. In one embodiment, the third layer 122a and the fourth layer 122b can include same material but with different composition ratios. For example, the third layer 122a can include Al_{1-y35}In_{y35}P and the fourth layer 122b can include Al_{1-y36}In_{y36}P while y35<y36, thus the third layer 122a and the fourth layer 122b respectively have the tensile strain and the compressive strain with respect to the base 108. As the third layer 122a and the fourth layer 122b are AlInP, the wavelengths corresponding to the third bandgap (ΔE3) and the fourth bandgap (ΔE4) increase with the indium atomic ratios (y35, y36). In one embodiment, when the base 108 is the GaAs substrate and the peak wavelength of the light emitted from the active structure 104 is between 580 nm to 620 nm, y35 can be between 0.3 to 0.4 and y36 can be between 0.59 to 0.69 so that the third bandgap (ΔE3) can have a corresponding wavelength between 515 nm to 525 nm and the fourth bandgap (ΔE4) can have a corresponding wavelength between 535 nm to 605 nm. In one embodiment, the third layer 122a and the fourth layer 122b can include different materials. For example, the third layer 122a can include Ga_{1-y37}In_{y37}P and the fourth layer 122b can include Al_{1-y38}In_{y38}P while y37<y38, thus the third layer 122a and the fourth layer 122b respectively have the tensile strain and the compressive strain with respect to the base 108. When the third layer 122a is GaInP, the wavelength corresponding to the third bandgap (ΔE3) increases with the indium atomic ratio (y37). In one embodiment, when the base 108 is the GaAs substrate and the peak wavelength of the light emitted from the active structure 104 is between 580 nm to 620 nm, y37 can be between 0.3 to 0.4 and y38 can be between 0.59 to 0.69, so that the third bandgap (ΔE3) can have a corresponding wavelength between 560 nm to 605 nm and the fourth bandgap (ΔE4) can have a corresponding wavelength between 535 nm to 605 nm.

In above two embodiments, through adjusting indium atomic ratios of the third layer 122a and the fourth layer 122b, the third layer 122a and the fourth layer 122b respectively have the tensile strain and the compressive strain with respect to the base 108, and the wavelengths corresponding to the third bandgap (ΔE3) of the third layer 122a and the fourth bandgap (ΔE4) of the fourth layer 122b can be smaller than the peak wavelength of the light. When the second semiconductor structure 102 is the n-type semiconductor, the third layer 122a with the tensile strain can improve the electron mobility of the second semiconductor structure 102. When the second semiconductor structure 102 is the p-type semiconductor, the fourth layer 122b with the compressive strain can improve the hole mobility of the second semiconductor structure 102. In other words, the third layer 122a and the fourth layer 122b can respectively improve the electron mobility and the hole mobility of the second semiconductor structure 102 since they have opposite strains, so that the carrier recombination speed of the semiconductor device 10B can be increased.

The positions, relative relationships, and material compositions of other layers or structures as well as structural variations in the semiconductor device 10B have been described in detail in previous embodiments, and are not repeatedly described herein.

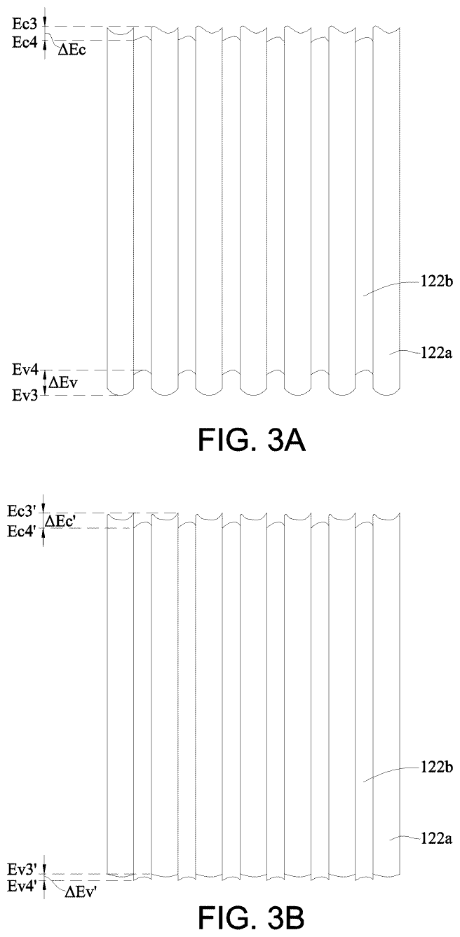

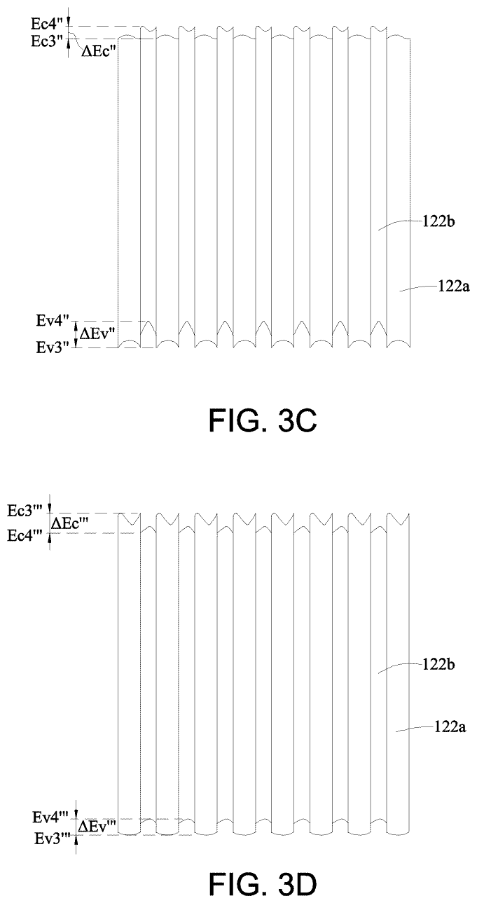

FIGS. 3A to 3D show schematic figures of band structure according to superlattice structures in different embodiments of the present disclosure. To facilitate explanation, FIGS. 3A to 3D are illustrated by the second superlattice structures 122. However, one having ordinary skills in this art should understand that either the first superlattice structure 106 or the second superlattice structure 122 can have the band structures shown in FIGS. 3A, 3B, 3C or 3D.

Referring to FIG. 3A, the plurality of third layers 122a and the plurality of fourth layers 122b are alternately stacked with each other to form the second superlattice structure 122. In this embodiment, the plurality of third layers 122a has the third valence band (Ev3) and the third conduction band (Ec3), and the plurality of fourth layers 122b has the fourth valence band (Ev4) and the fourth conduction band (Ec4). The maximum difference between the third valence band (Ev3) and the fourth valence band (Ev4) is defined as the gap of valence band (ΔEv), and the maximum difference between the third conduction band (Ec3) and the fourth conduction band (Ec4) is defined as a gap of conduction band (ΔEc). In this embodiment, the third conduction band (Ec3) is larger than the fourth conduction band (Ec4), and the fourth valence band (Ev4) is larger than the third valence band (Ev3). In one embodiment, the gap of valence band (ΔEv) can be larger than the gap of conduction band (ΔEc). In one embodiment, the gap of valence band (ΔEv) can be in a range of 0.05 eV to 1 eV. In one embodiment, the gap of conduction band (ΔEc) can be in a range of 0.05 eV to 1 eV. With respect to the base 108, the second superlattice structure 122 can have no strain. For example, the third layer 122a can include Al_{0.3}Ga_{0.15}In_{0.5}P and the fourth layer 112b can include Al_{0.15}Ga_{0.35}In_{0.5}P, and the gap of valence band (ΔEv) is about 0.13 eV and the gap of conduction band (ΔEc) is about 0.08 V. When the second semiconductor structure 102 is the n-type semiconductor, forming the gap of conduction band (ΔEc) mentioned above between the third conduction band (Ec3) and the fourth conduction band (Ec4) can provide good carrier confinement effect.

Referring to FIG. 3B, in this embodiment, the plurality of third layers 122a has a third valence band (Ev3′) and a third conduction band (Ec3′), and the plurality of fourth layers 122b has a fourth valence band (Ev4′) and a fourth conduction band (Ec4′). Similarly, the maximum difference between the third valence band (Ev3′) and the fourth valence band (Ev4′) is defined as the gap of valence band (ΔEv′), and the maximum difference between the third conduction band (Ec3′) and the fourth conduction band (Ec4′) is defined as the gap of conduction band (ΔEc′). In this embodiment, the third conduction band (Ec3′) is larger than the fourth conduction band (Ec4′), and the fourth valence band (Ev4′) is smaller than the third valence band (Ev3′). In this embodiment, the gap of valence band (ΔEv′) can be smaller than the gap of conduction band (ΔEc′). For example, the gap of valence band (ΔEv′) can be smaller than 0.05 eV and the gap of conduction band (ΔEc′) can be between 0.05 eV to 1 eV. With respect to the base 108, the second superlattice structure 122 can have strain. For example, the third layer 122a can include Al_{0.7}Ga_{0.3}As_{0.9}Sb_{0.1} and the fourth layer 122b can include Al_{0.15}Ga_{0.35}In_{0.5}P, and the gap of valence band (ΔEv′) is about 0.13 eV and the gap of conduction band (ΔEc′) is about 0.08 eV. When the second semiconductor structure 102 is the n-type semiconductor, forming the gap of conduction band (ΔEc′) between the third conduction band (Ec3′) and the fourth conduction band (Ec4′) can provide good carrier confinement effect.

Referring to FIG. 3C, in this embodiment, the plurality of third layers 122a has a third valence band (Ev3″) and a third conduction band (Ec3″), and the plurality of fourth layers 122b has a fourth valence band (Ev4″) and a fourth conduction band (Ec4″). The maximum difference between the third valence band (Ev3″) and the fourth valence band (Ev4″) is defined as the gap of valence band (ΔEv″), and the maximum difference between the third conduction band (Ec3″) and the fourth conduction band (Ec4″) is defined as the gap of conduction band (ΔEc″). In this embodiment, the third conduction band (Ec3″) is smaller than the fourth conduction band (Ec4″) and the fourth valence band (Ev4″) is larger than the third valence band (Ev3″). In this embodiment, the gap of valence band (ΔEv″) can be between 0.05 eV to 1 eV and the gap of conduction band (ΔEc″) can be between 0.05 eV to 1 eV. With respect to the base 108, the second superlattice structure 122 can have strain. For example, the third layer 122a can include Al_{0.5}In_{0.5}P and the fourth layer 122b can include In_{0.5}Al_{0.5}P_{0.8}Sb_{0.2}, and the gap of valence band (ΔEv″) is about 0.1 eV and the gap of conduction band (ΔEc″) is about 0.05 eV. When the second semiconductor structure 102 is the p-type semiconductor, forming the gap of valence band (ΔEv″) between the third valence band (Ev3″) and the fourth valence band (Ev4″) can provide good carrier confinement effect. In this embodiment, since the fourth layer 122b includes antimony (Sb), concentration of the two-dimensional hole gas (2DHG) and hole mobility within the second semiconductor structure 102 can be increased, so as to reduce serial resistance and increase carrier recombination speed of the semiconductor device 10A.

Referring to FIG. 3D, in this embodiment, the plurality of third layers 122a has a third valence band (Ev3′″) and a third conduction band (Ec3′″), and the plurality of fourth layers 122b has a fourth valence band (Ev4′″) and a fourth conduction band (Ec4′″). The maximum difference between the third valence band (Ev3′″) and the fourth valence band (Ev4′″) is defined as the gap of valence band (ΔEv′″), and the maximum difference between the third conduction band (Ec3′″) and the fourth conduction band (Ec4′″) is defined as the gap of conduction band (ΔEc′″). In this embodiment, the third conduction band (Ec3′″) is larger than the fourth conduction band (Ec4′″) and the fourth valence band (Ev4′″) is larger than the third valence band (Ev3′″). In this embodiment, the gap of valence band (ΔEv′″) can be between 0.05 eV to 1 eV and the gap of conduction band (ΔEc′″) can be between 0.05 eV to 1 eV. With respect to the base 108, the second superlattice structure 122 can have strain. For example, the third layer 122a can include Al_{0.35}Ga_{0.15}In_{0.5}P_{0.9}Sb_{0.1} and the fourth layer 122b can include Al_{0.15}Ga_{0.35}In_{0.5}P, and the gap of valence band (ΔEv′″) is about 0.1 eV and the gap of conduction band (ΔEc′″) is about 0.11 eV. When the second semiconductor structure 102 is the n-type semiconductor, forming the gap of conduction band (ΔEc′″) between the third conduction band (Ec3′″) and the fourth conduction band (Ec4′″) can provide good carrier confinement effect.

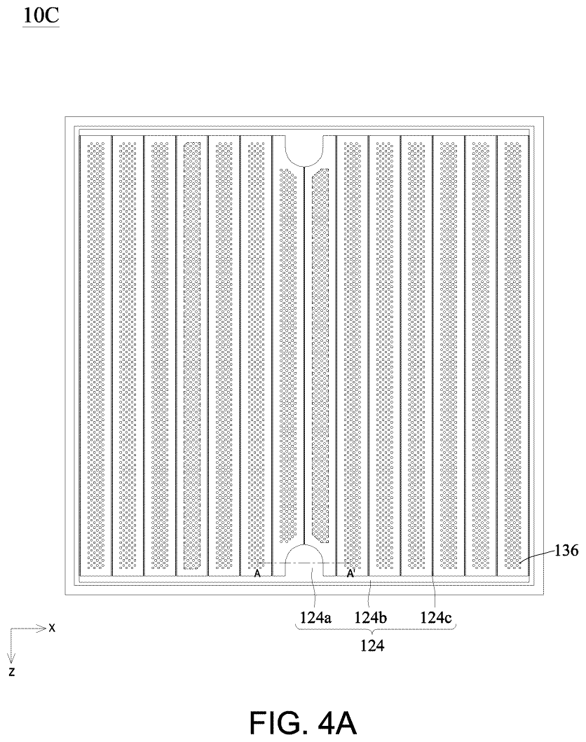

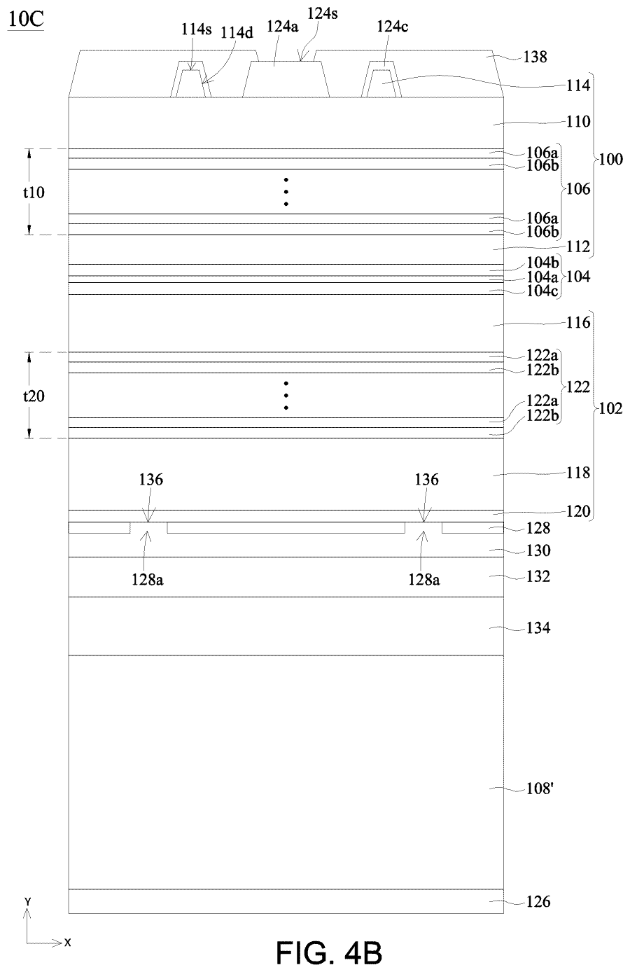

FIG. 4A shows a top schematic view of a semiconductor device 10C according to one embodiment of the present disclosure, and FIG. 4B is a schematic cross-sectional view of the semiconductor device 10C along section line A-A′ in FIG. 4A. In the embodiment shown in FIG. 4A, the semiconductor device 10C is formed by transferring the first semiconductor structure 100, the second semiconductor structure 102 and the active structure 104 shown in FIG. 2 to the base 108′ through a bonding process. That is to say, in this embodiment, the base 108′ is the bonding substrate, and the second semiconductor structure 102 is located on the base 108′ and closer to the base 108′ than the first semiconductor structure 100.

As shown in FIGS. 4A and 4B, the semiconductor device 10C further includes a first electrode 124 and a second electrode 126 which are disposed at two opposite sides of the base 108′ respectively. The first electrode 124 and the second electrode 126 electrically connect the semiconductor device 10C to an external power source or other components for operating the semiconductor device 10C. The first electrode 124 and the second electrode 126 can include metal oxide, metal or alloy. For example, the metal oxide can include, but not limited to, indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), zinc oxide (ZnO), indium tungsten oxide (IWO), or indium zinc oxide (IZO). The metal can include, but not limited to, germanium (Ge), beryllium (Be), zinc (Zn), gold (Au), platinum (Pt), titanium (Ti), aluminum (Al), nickel (Ni), or copper (Cu). The alloy can include two or more metals selected from the abovementioned metals, such as germanium-gold-nickel (GeAuNi), beryllium gold (BeAu), germanium gold (GeAu), or zinc gold (ZnAu).

As shown in FIG. 4A, in this embodiment, the first electrode 124 includes a pad 124a, a plurality of first extending portions 124b connecting the pad 124a, and a plurality of second extending portions 124c connecting the plurality of first extending portions 124b. In some embodiment, the first electrode 124 can include multiple pads 124a, and the pads 124 can be connected by one of the plurality of second extending portions 124c. In top view, the plurality of first extending portions 124b extends along X-direction, and the plurality of second extending portions 124c extends along Z-direction and are perpendicular to the plurality of first extending portions 124b. Each of the first extending portions 124b has a first width W1 (along Z-direction), and each of the second extending portions 124c has a second width W2 (along X-direction). The second width can be smaller than the first width W1. In this embodiment, the pad 124a connects the external power source or components through a wire, then currents flowed into the pad 124a can spread into the semiconductor device 10C uniformly through the plurality of first extending portions 124b and the plurality of second extending portions 124c.

As shown in FIG. 4B, the semiconductor device 10C can optionally include an insulating structure 128, a conductive structure 130, a reflecting structure 132 and a bonding structure 134. In this embodiment, the insulating structure 128 is located below the second semiconductor structure 102 and directly contact the second semiconductor contact layer 120. As shown in FIG. 4B, the insulating structure 128 can include a plurality of holes 128a. The conductive structure 130 is located below the insulating structure 128. In one embodiment, the conductive structure 130 fills in the plurality of holes 128a to contact the second semiconductor contact layer 120 directly, so as to form a plurality of current passages 136. As shown in FIGS. 4A and 4B, the plurality of current passages 136 is not overlapped with the first electrode 124 along Y-direction for spreading the currents uniformly. It should be noticed that FIG. 4A is actually a top perspective view of the semiconductor device 10C, so as to clearly show corresponding positions of the plurality of current passages 136 (or the plurality of holes 128a) projected on an upper surface of the semiconductor device 10C along the Y-direction. Since the insulating structure 128 and the conductive structure 130 are within the semiconductor device 10C, the plurality of current passages 136 (or the plurality of holes 128a) cannot be directly observed from appearance of the semiconductor device 10C. In some embodiments, each of the current passages 136 (or each of the holes 128a) has a top-view shape of circle, ellipse or polygon, for example, triangle, rectangle, pentagon or hexagon.

The insulating structure 128 can include electrically insulating materials, such as oxide or fluoride. The oxide is, for example, silicon dioxide (SiOx), and the fluoride is, for example, magnesium fluoride (MgFx). In some embodiments, the insulating structure 128 can include an electrically insulating material, such as a low-refractive-index electrical insulating material with a refractive index lower than 1.4, such as magnesium fluoride (MgFx). The conductive structure 130 can include transparent conductive oxides, such as indium tin oxide (ITO), indium oxide (InO), tin oxide (SnO), cadmium tin oxide (CTO), antimony tin oxide (ATO), Al-doped ZnO (AZO), zinc tin oxide (ZTO), Ga-doped ZnO (GZO), zinc oxide (ZnO), indium cerium oxide (ICO), indium tungsten oxide (IWO), indium titanium oxide (ITiO), indium zinc oxide (IZO), indium gallium oxide (IGO) or gallium aluminum zinc oxide (GAZO).

As shown in FIG. 4B, the reflecting structure 132 is located below the conductive structure 130. In one embodiment the reflecting structure 132 can have high reflectivity to the light emitted from the active structure 104, such as 80% or higher. The reflecting structure 132 can include conductive material, such as metal or alloy. The metal can include gold (Au), silver (Ag) or aluminum (Al). The bonding structure 134 is located between the reflecting structure 132 and the base 108′. The bonding structure 134 can include conductive material, such as metal or alloy. In one embodiment, the bonding structure 134 can be formed by soldering, eutectic bonding or thermocompression bonding to bond the reflecting structure 132 to the base 108′.

In one embodiment, the first semiconductor contact layer 114 can be patterned to locate below the plurality of first extending portions 124b and the plurality of second extending portions 124c of the first electrode 124. As shown in FIG. 4B, along Y-direction, the first semiconductor contact layer 114 is overlapped with the second extending portions 124c and not overlapped with the pad 124a. More specifically, the first semiconductor contact layer 114 has an upper surface 114s and a side surface 114d, and each of the first extending portions 124b and/or each of the second extending portions 124c directly contacts the upper surface 114s and the side surface 114d for increasing electrical contact area.

Referring to FIG. 4B, the semiconductor device 10C can optionally include protecting layer 138 covering the first semiconductor structure 100 and the first electrode 124, so as to protect the semiconductor device 10C and prevent external pollutants or moisture from affecting photoelectric characteristics of the semiconductor device 10C. More specifically, the protecting layer 138 covers on the plurality of first extending portions 124b, the plurality of second extending portions 124c and a part of a top surface 124s of the pad 124a. In other words, the top surface 124s of the pad 124a is partially exposed to connect with the external power source or components. The protecting layer 138 can include insulating material, such as SiNx or SiOx. The positions, relative relationships, and material compositions of other layers or structures as well as structural variations in the semiconductor device 10C have been described in detail in previous embodiments, and are not repeatedly described herein. Furthermore, it should be realized that the semiconductor device 10C shown in FIG. 4B is not limited to include both of the first superlattice structure 106 and the second superlattice structure 122. In other embodiments, the semiconductor device 10C can include only one of the first superlattice structure 106 and the second superlattice structure 122.

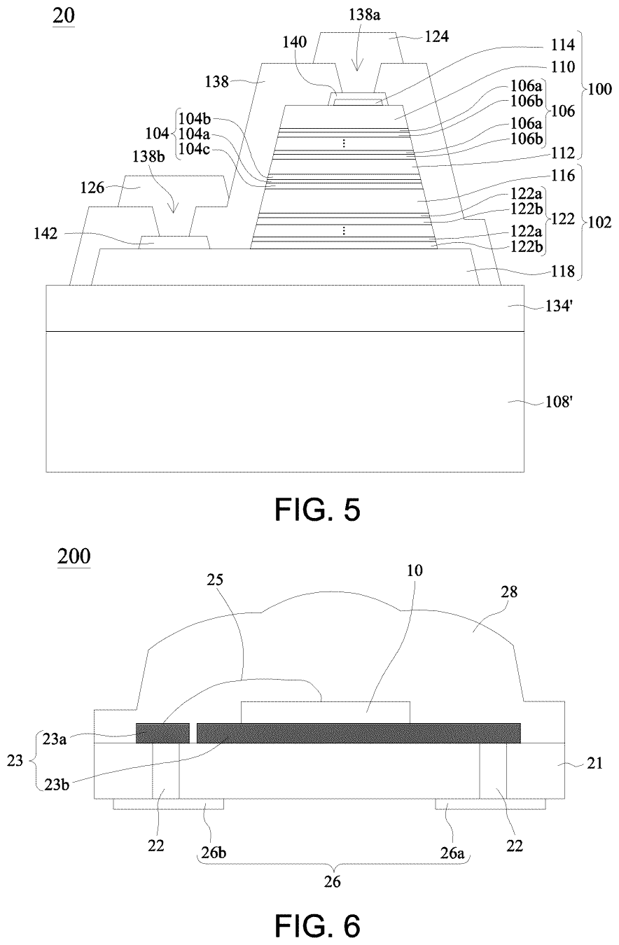

FIG. 5 is a schematic cross-sectional view of a semiconductor device 20 according to one embodiment of the present disclosure, which has similar components as the semiconductor device 10C. As shown in FIG. 5, there is a difference between the semiconductor device 20 and the semiconductor device 10C that the first electrode 124 and the second electrode 126 of the semiconductor device 20 are located at the same side of the base 108′. In one embodiment, the semiconductor device 20 can further include a first metal contact layer 140 and a second metal contact layer 142. The first metal contact layer 140 forms on the first semiconductor contact layer 114 and electrically connecting the first semiconductor contact layer 114, and the second metal contact layer 142 forms on the fourth semiconductor layer 118 and electrically connecting the fourth semiconductor layer 118. Furthermore, the protecting layer 138 can include a first opening 138a and a second opening 138b respectively corresponding to the first metal contact layer 140 and the second metal contact layer 142, so as to expose a part of top surface of the first metal contact layer 140 and a part of top surface of the second metal contact layer 142. The first electrode 124 fills in the first opening 138a and directly contact the first metal contact layer 140 to form electrical connection with the first metal contact layer 140, and the second electrode 126 fills in the second opening 138b and directly contact the second metal contact layer 142 to form electrical connection with the second metal contact layer 142. As shown in FIG. 5, side surfaces of the first semiconductor structure 100, the second semiconductor 102 and the active structure 104 can be inclined, thus the protecting layer 138 can conformally attach to the first semiconductor structure 100, the second semiconductor 102 and the active structure 104 easily. In this embodiment, for disposing the first electrode 124 and the second electrode 126 at the same side of the base 108′, a width of the fourth semiconductor layer 118 can be larger than a width of the second superlattice structure 122 and a width of the third semiconductor structure 116, so as to form the second metal contact layer 142 and the second electrode 126 on the upper surface of the fourth semiconductor layer 118.

Materials of the first metal contact layer 140 and the second metal contact layer 142 can be determined respectively according to the material of the first semiconductor contact layer 114 and the material of the fourth semiconductor layer 118, so as to form an electrical contact (such as an ohmic contact) between the first metal contact layer 140 and the first semiconductor contact layer 114 and between the second metal contact layer 142 and the fourth semiconductor layer 118. The first metal contact layer 140 and the second metal contact layer 142 can respectively include conductive material, such as metal or alloy. The metal includes germanium (Ge), beryllium (Be), zinc (Zn), gold (Au), nickel (Ni), or copper (Cu). The alloy, for example, includes two or more metals selected from the above metals, such as germanium-gold-nickel (GeAuNi), beryllium gold (BeAu), germanium gold (GeAu), or zinc gold (ZnAu). The first metal contact layer 140 and the second metal contact layer 142 can include different materials. In one embodiment, the first metal contact layer 140 includes germanium gold (GeAu) and the second metal contact layer 142 includes beryllium gold (BeAu). As shown in FIG. 5, the first metal contact layer 140 may directly contact an upper surface and a side surface of the first semiconductor contact layer 114 to increase contact area therebetween. In another embodiment, the first metal contact layer 140 can only contact the upper surface of the first semiconductor contact layer 114.

In one embodiment, the protecting layer 138 can optionally include a distributed Bragg reflector (DBR). The distributed Bragg reflector can include a plurality of first dielectric layers and a plurality of second dielectric layers alternately stacked with each other, and the plurality of first dielectric layers and a plurality of second dielectric layers have different refractive indices. For the semiconductor device 20, when the light emitted from the active structure 104 is extracted from the base 108′, the protecting layer 138 with DBR helps to reflect the light towards the base 108′ to facilitate light extraction. The positions, relative relationships, and material compositions of other layers or structures as well as structural variations in the semiconductor device 20 have been described in detail in previous embodiments, and are not repeatedly described herein. Furthermore, it should be realized that the semiconductor device 20 shown in FIG. 5 is not limited to include both of the first superlattice structure 106 and the second superlattice structure 122. In other embodiments, the semiconductor device 20 can include one of the first superlattice structure 106 and the second superlattice structure 122 only.

FIG. 6 is a schematic cross-sectional view of a package structure 200 of a semiconductor device 10 in one embodiment in accordance with the present disclosure. The package structure 200 includes a semiconductor device 10, a packaging mount 21, a first electrical connection structure 23, a bonding wire 25, a second electrical connection structure 26, and an encapsulating structure 28. The packaging mount 21 can include ceramic or glass. The packaging mount 21 has multiple channels 22, which can be filled with electrically conductive material such as metal for facilitating electrical conduction or/and heat dissipation. The first electrical connection structure 23 is located on the surface of one side of the packaging mount 21 and can include an electrically conductive material such as metal. The semiconductor device 10 is located on the first electrical connection structure 23 and can be applied to any of the embodiments in the present disclosure, such as aforementioned the semiconductor device 10A, the semiconductor device 10B, the semiconductor device 10C or the semiconductor device 20. In this embodiment, the first electrical connection structure 23 includes a first contact pad 23a and the second contact pad 23b, and the semiconductor device 10 can electrically connect to the second contact pad 23b of the first electrical connection structure 23 by the bonding wire 25. The bonding wire 25 can include metal, such as gold (Au), silver (Ag), copper (Cu), aluminum (Al), or the alloy including one of the aforementioned metals. The second electrical connection structure 26 is located on the surface of another side of the packaging mount 21. In this embodiment, the second electrical connection structure 26 includes a third contact pad 26a and a fourth contact pad 26b. The third contact pad 26a and the fourth contact pad 26b can connect to the first electrical connection structure 23 electrically through the channels 22. In one embodiment, the second electrical connection structure 26 can additionally include a thermal pad (not shown) located, for example, between the third contact pad 26a and the fourth contact pad 26b. The encapsulating structure 28 can protect the semiconductor device 10 by covering the semiconductor device 10. More specifically, the encapsulating structure 28 can include resin, such as epoxy, silicone. The encapsulating structure 28 can additionally include a plurality of wavelength conversion particles (not shown) to convert a first light emitted from the semiconductor device 10 into a second light.

Based on the above, the present disclosure can provide a semiconductor device and a package structure thereof, and the structural design of which helps to improve optoelectronic characteristics of the semiconductor device (for example, lowering the operating bias or improving speed of carrier recombination). The semiconductor device or the package structure disclosed in this disclosure can be applied to products in various fields, such as illumination, medical care, display, communication, sensing, or power supply system, for example, can be used in a light fixture, monitor, mobile phone, tablet, an automotive instrument panel, a television, computer, wearable device (such as watch, bracelet or necklace), traffic sign, outdoor display, or medical device.

The embodiments of the present disclosure will be described in detail below with reference to the drawings. In the descriptions of the specification, specific details are provided for a full understanding of the present disclosure. The same or similar components in the drawings will be denoted by the same or similar symbols. It is noted that the drawings are for illustrative purposes only and do not represent the actual dimensions or quantities of the components. Some of the details may not be fully sketched for the conciseness of the drawings.

What is claimed is:

1. A semiconductor device, comprising:
a first semiconductor structure having a first conductivity type, and comprising a plurality of first layers and a plurality of second layers which are alternately stacked;
a second semiconductor structure located on the first semiconductor structure and having a second conductivity type opposite to the first conductivity type; and
an active layer located between the first semiconductor structure and the second semiconductor structure;
wherein the plurality of first layers and the plurality of second layers include indium and phosphorus; and
wherein the plurality of first layers has a first indium atomic percentage and the plurality of second layers has a second indium atomic percentage different from the first indium atomic percentage.

2. The semiconductor device according to claim 1, wherein the plurality of first layers or the plurality of second layers comprises (Aₓ₁B₁₋ₓ₁)_{1-y1}In_{y1}P, wherein A and B are selected from group III elements other than indium, wherein 0≤x1≤1, and 0<y1≤1.

3. The semiconductor device according to claim 2, wherein A is aluminum and B is gallium, and wherein the plurality of first layers, the plurality of second layers or both comprises (Alₓ₂Ga₁₋ₓ₂)_{1-y1}In_{y1}P, wherein 0<x2<1, and 0<y1<1.

4. The semiconductor device according to claim 2, wherein the plurality of first layers comprises Al_{1-y2}In_{y2}P and the plurality of second layers comprises Ga_{1-y3}In_{y3}P, wherein 0.59<y2<0.69, 0.3<y3<0.4.

5. The semiconductor device according to claim 4, wherein the plurality of first layers has a first lattice constant, and the plurality of second layers has a second lattice constant different from the first lattice constant.

6. The semiconductor device according to claim 2, wherein the plurality of first layers has a first bandgap and the plurality of second layers has a second bandgap, and the active layer has a third bandgap smaller than the first bandgap and the second bandgap.

7. The semiconductor device according to claim 2, wherein one of the plurality of first layers has a first conduction band, and one of the plurality of second layers has a second conduction band different from the first conduction band.

8. The semiconductor device according to claim 7, wherein a gap of conduction band between the first conduction band and the second conduction band is in a range of 0.05 eV to 1 eV.

9. The semiconductor device according to claim 1, wherein the first indium atomic percentage and the second indium atomic percentage are between 30% to 70%.

10. The semiconductor device according to claim 1, wherein one of the plurality of first layers has a first thickness and one of the plurality of second layers has a second thickness, and the second thickness is equal to or smaller than the first thickness.

11. The semiconductor device according to claim 10, wherein the first thickness and the second thickness are in a range of 30 Å to 300 Å.

12. The semiconductor device according to claim 1, wherein the second semiconductor structure includes a plurality of third layers and a plurality of fourth layers which are alternately stacked.

13. The semiconductor device according to claim 12, wherein the plurality of third layers and the plurality of fourth layers include indium and phosphorus; and
wherein the plurality of third layers has a third indium atomic percentage and the plurality of fourth layers has a fourth indium atomic percentage different from the third indium atomic percentage.

14. The semiconductor device according to claim 13, wherein the plurality of third layers or the plurality of fourth layers comprises Al_{1-y4}In_{y4}P, wherein 0<y4<1.

15. The semiconductor device according to claim 12, wherein the plurality of third layers or the plurality of fourth layers comprises In_{y5}C_{1-y5}Sbₓ₃D₁₋ₓ₃; and
wherein C is selected from group III elements other than indium, and D is selected from group V elements other than antimony, and 0≤x3≤1, and 0<y5≤1.

16. The semiconductor device according to claim 12, wherein one of the plurality of third layers has a third conduction band, and one of the plurality of fourth layers has a fourth conduction band different from the third conduction band.

17. The semiconductor device according to claim 16, wherein a gap of the conduction band between the third conduction band and the fourth conduction band is in a range of 0.05 eV to 1 eV.

18. The semiconductor device according to claim 1, further comprising a base connecting to the second semiconductor structure and a bonding structure located between the second semiconductor structure and the base.

19. The semiconductor device according to claim 18, further comprising a reflecting structure located between the second semiconductor structure and the bonding structure.

20. The semiconductor device according to claim 18, further comprising an insulating structure and a conductive structure, the insulating structure connecting the second semiconductor structure and including a plurality of holes, the conductive structure disposed between the insulating structure and the bonding structure and connected to the second semiconductor structure through the plurality of holes.
